(19) United States
(12) Patent Application Publication
(10) Pub. No.: US 2007/0200121 A1
(43) Pub. Date: Aug. 30, 2007

(54) Multi-colored LED array with improved color uniformity

(75) Inventors: Martijn H. R. Lankhorst, Eindhoven (NL); Rob Hendriks, Overlangel (NL)

Correspondence Address: PATENT LAW GROUP LLP, 2635 NORTH FIRST STREET, SUITE 223, SAN JOSE, CA, 95134, US

(73) Assignee: Lumileds Lighting U.S., LLC

(21) Appl. No.: 11/361,109

(22) Filed: Feb. 24, 2006

(51) Int. Cl. H01L 33/00; H01L 31/12; H01L 27/15; H01L 29/26

(52) U.S. Cl. 257/79

(57) ABSTRACT

A backlight uses an array of red, green, and blue LEDs in a mixing chamber. The mixing chamber has reflecting surfaces and a top opening for illuminating LCD layers. The LEDs are arranged in clusters of red, green, and blue LEDs, where there are at least two types of clusters used in the backlight for improved color uniformity across the LCD screen. Examples of a set of two clusters are RGBBGR with BGRRGB, and GRBRG with RGBGR. In one embodiment, clusters of one type form alternate rows in the array, and clusters of the other type form interleaved rows. In another embodiment, the cluster types in a row alternate, and the cluster types in a column alternate like a checkerboard to improve color uniformity. In one embodiment, there is an odd number of rows so that the same cluster type will be at the four corners of the array. Currents to the red, green, and blue LEDs adjust the white point of the display.

### FIELD OF INVENTION

This invention relates to illumination devices using multi-colored light emitting diodes (LEDs) and, in particular, to techniques for obtaining better color uniformity across the light emitting area of an illumination device, such as a backlight for a liquid crystal display (LCD).

### BACKGROUND

Liquid crystal displays (LCDs) are commonly used in cell phones, personal digital assistants, laptop computers, desktop monitors, and television applications. One embodiment of the present invention deals with a color, transmissive LCD that requires backlighting, where the backlight may contain red, green, and blue LEDs.

FIG. 1 is a cross-sectional view of a color, transmissive LCD 10 that includes a backlight 12. The backlight contains an array of red, green, and blue LEDs 14 whose combined light forms white light.

The backlight 12 ideally provides homogenous light to the back surface of the display. Providing homogenous white light using physically spaced LEDs is very difficult in a shallow backlight box. The backlight box has diffusively reflective bottom and side walls to mix the red, green, and blue light. The inner surfaces may be painted white. Mixing optics 16, such as a diffuser, improves the color mixing.

Above the mixing optics 16 are conventional LCD layers 18, typically consisting of polarizers, RGB filters, a liquid crystal layer, a thin film transistor array layer, and a ground plane layer. The electric fields created at each pixel location, by selectively energizing the thin film transistors at each pixel location, causes the liquid crystal layer to change the polarization of the white light at each pixel location. The RGB filters only allow the red, green, or blue component of the white light to be emitted at the corresponding RGB pixel locations. LCDs are well known and need not be further described.

As LED technology advances, the light output and efficiency of power LEDs increase, and fewer LEDs are needed to provide the light output needed for an LCD. Using fewer LEDs typically reduces the cost of the backlight. Increasing the pitch of the LEDs makes it more difficult to provide adequate color uniformity across the LCD screen, especially with a relatively shallow backlight box.

Therefore, what is needed are new techniques for improving the color uniformity of a backlight using LEDs across an LCD.

### SUMMARY

Various techniques are described herein for creating an improved backlight for backlighting an LCD. In one embodiment, the backlight uses an array of red, green, and blue LEDs in a mixing chamber. The mixing chamber has reflective walls, a reflective bottom surface, and a light emitting top area for illuminating the LCD layers overlying the mixing chamber.

The LEDs in the backlight are arranged in clusters. In one example, each cluster has six LEDs with two reds, two greens, and two blues, and the clusters form a 6×5 array for a 32 inch television screen. Various sequences of the RGB LEDs in the cluster are described. Other sizes of clusters and arrays are also described.

In one embodiment, two types of clusters are used, and each cluster has the same number of RGB LEDs so as to have the same white point. All clusters in the same row are the same. The rows alternate between clusters of the first type and clusters of the second type to improve color uniformity. In one embodiment, the sequence in a cluster is symmetrical. In another embodiment, the sequence in a cluster is asymmetrical. Preferably, the number of rows is odd so that each of the four corners has the same cluster.

In another embodiment, there are two types of clusters in each row, and the clusters alternate. The clusters along a column also alternate to produce a checkerboard pattern of clusters. This also improves color uniformity across the LCD.

The arrangement, selection, and control of the multicolored LEDs may be tailored to achieve any desired white point specified by the display manufacturer.

### BRIEF DESCRIPTION OF THE DRAWINGS

FIG. 1 is a cross-section of a prior art, color, transmissive LCD using a white light source.

FIG. 2 is a top down view of a backlight for an LCD showing an arrangement of LEDs in accordance with one embodiment of the invention.

FIG. 3 is a top down view of a backlight for an LCD showing another arrangement of LEDs in accordance with one embodiment of the invention.

FIG. 4 is a top down view of a backlight for an LCD showing another arrangement of LEDs in accordance with one embodiment of the invention.

FIG. 5 is a cross-sectional view of an LCD, such as in a television or monitor, using the inventive backlight.

### DETAILED DESCRIPTION

Embodiments of the present invention provide improved color uniformity over a large area. Applications of embodiments of the invention include general illumination and backlighting.

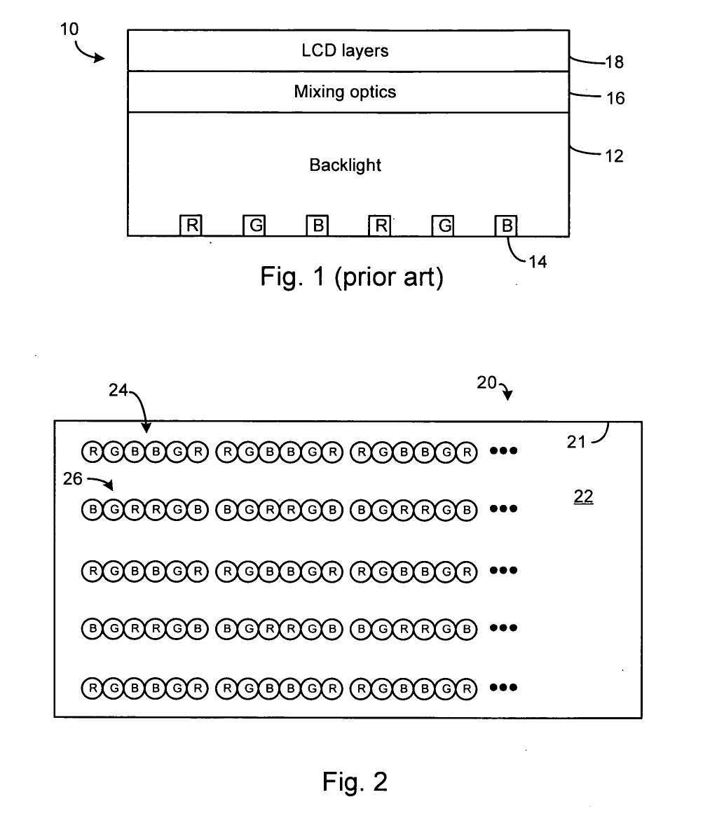

FIG. 2 is a top down view of a portion of a backlight 20 containing an array of LEDs. The backlight of FIG. 2, and the other backlights described, may replace backlight 12 in FIG. 1. The LEDs are arranged in clusters. Although there is a space shown between clusters, all LEDs in a single row may also be equally spaced, with no additional space between clusters. In one embodiment, the pitch of the LEDs in a cluster is about 10-15 mm. The LEDs may be mounted on a printed circuit board strip, and the board secured to the bottom surface of the backlight cavity.

The backlight may be formed of aluminum sheeting, and its inner walls 21 and base 22 are coated with a diffusively reflective material, such as white paint. Various types of reflective material are commercially available and are well known. In another embodiment, the side walls are covered with a specular film. In one embodiment, the depth of the backlight is 25-40 mm.

A first cluster type 24 is formed of a sequence of six LEDs: RGBBGR. The pattern is symmetric. Applicants have found that symmetric clusters with the same number of LEDs of each color provide a color uniformity that is better than asymmetric clusters such as RGBRGB, etc.

In FIG. 2, the same cluster type 24 (RGBBGR) is repeated along the first row. In one example, there are six clusters 24 in a row for a 32 inch TV screen. In the second row, a different set of clusters 26 are arranged end to end, each cluster 26 having the sequence BGRRGB. The same numbers of red, green, and blue LEDs are in both clusters 24 and 26, so the overall white point does not change from cluster 24 to cluster 26. Since the same color LEDs are not directly aligned in a column, there is better mixing of the colors, in contrast to a layout where the same clusters are used in every row.

In the example above, the LEDs in the 2 and 5 positions in a cluster do not change position between the two cluster types. The LEDs in positions 1 and 3 switch, and the LEDs in positions 4 and 6 switch, between the cluster types. This particular change in pattern is advantageous since, in the top row, two reds and two blues are grouped together along the row, while the greens are separated. Placing two LEDs of the same color together is detrimental to color mixing but is unavoidable in a symmetric cluster pattern having equal numbers of the LED colors. In the next row with the clusters 26, the two reds and two blues do not align with the two reds and two blues in the top row, thus preventing concentrations of red and blue.

The rows of clusters 24 and 26 alternate. In the example of a 32 inch TV screen, there are 5 rows (180 LEDs total). The number of rows depends on the particular LEDs used, the size of the backlight, and the light output specifications of the backlight. It is beneficial to have the same cluster type in the four corners of the backlight to cause the color at each corner to be identical. This is achieved by making the number of rows an odd number.

Other cluster types that may be used in the backlight of FIG. 2 include: RBGGBR and GBRRBG as cluster types in alternating rows; or GRBBRG and BRGGRB as cluster types in alternating rows. More than two types of clusters may be used in a backlight for additional color mixing. Clusters of more than six LEDs may also be used.

Although the examples show LEDs arranged in row and columns, other patterns may also be used. Such patterns include zig-zag, wavy, circular, and polygonal patterns. Each cluster may also be in a shape other than a line, such as circular, polygonal, etc.

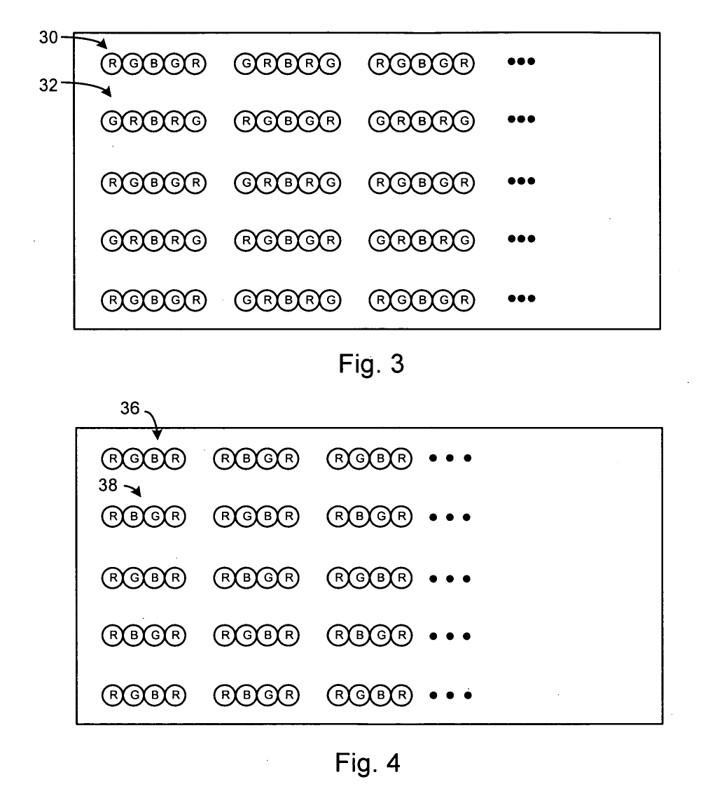

FIG. 3 illustrates another embodiment of a backlight using symmetrical clusters. To improve color uniformity, two cluster types are used. The cluster types alternate within a single row and in a single column like a checkerboard pattern for improved color mixing. In the example of FIG. 3, the first cluster type 30 is RGBGR, and the second cluster type 32 is GRBRG, both generating the same white point. Since it is beneficial to have the same cluster type in each corner of the screen, there should be an odd number of rows and columns. In one embodiment, there are seven columns and five rows for a 32 inch TV screen.

The same checkerboard pattern can be made with any of the 6-LED clusters, described above, for a further improvement in color uniformity.

Clusters having six LEDs with two LEDs of the same color provide a higher reliability than clusters with four or five LEDs without redundant LED colors. In a cluster where one of the RGB components is provided by only a single LED, failure of the LED, including a significant diminishing in brightness, has a noticeable effect on the color output of the cluster, leading to nonuniformity of color across the LCD. Failure of one LED in a six-LED cluster will have much less of an adverse effect.

FIG. 4 illustrates another embodiment of a backlight using asymmetrical clusters. Asymmetrical clusters have been found to provide less color uniformity than symmetrical clusters but, in some cases to reduce the number of LEDs or improve overall power efficiency, a trade-off is made to use asymmetrical clusters. As in FIG. 3, the cluster types alternate within a single row and in a single column like a checkerboard pattern for improved color mixing. In the example of FIG. 4, the first cluster type 36 is RGBR, and the second cluster type 38 is RBGR, both generating the same white point. To have the same cluster type in each corner of the screen, there should be an odd number of rows and columns. In one embodiment, there are nine columns and five rows for a 32 inch TV screen.

The above embodiments are improvements over the LED layout described in U.S. patent application publication 2005/0001537 A1, assigned to Lumileds Lighting, LLC, where a strip of LEDs forming an entire row is reversed for alternating rows. That technique simply reverses the sequence of LEDs while using the same clusters of LEDs in all rows. In Applicant's arrangements, multiple cluster types are used in the backlight.

The white point of the backlight may be controlled by controlling the current to each LED color. The LEDs of a single color may be connected in a combination of series and parallel and connected to a controllable current source. For the best color uniformity, all LEDs of the same color should have a similar flux and color point so the color output of each cluster is substantially the same. The white point for all clusters can then be adjusted by controlling the current to the red, green, and blue LEDs.

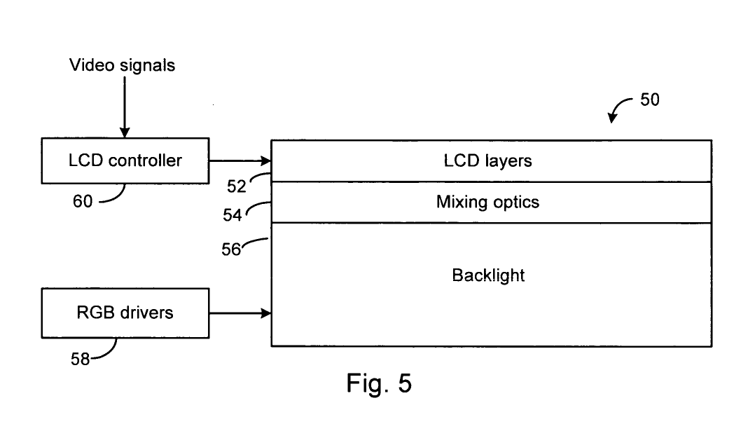

FIG. 5 illustrates a LCD 50, such as a television, a monitor, or other color display. The LCD layers 52 and mixing optics 54 may be the same as in FIG. 1. The backlight 56 is in accordance with the present invention. Drivers 58 for the red, green, and blue LEDs control the overall brightness and white point of the backlight 56. Video signals are fed to an LCD controller 60 that converts the signals to the XY control signals for the thin film transistor array so as to control the RGB pixel areas of the liquid crystal layer. The RGB pixel areas of the liquid crystal layer selectively pass light from the backlight 56 to RGB filters in the LCD layers 52. The top of the LCD layers 52 may be a display screen of a television or monitor having RGB pixels.

LEDs of colors other than red, green, and blue may also be used in the LCD 50 to create white light.

Having described the invention in detail, those skilled in the art will appreciate that given the present disclosure, modifications may be made to the invention without departing from the spirit and inventive concepts described herein. Therefore, it is not intended that the scope of the invention be limited to the specific embodiments illustrated and described.

What is claimed is:

1. A light emitting device comprising:
a light mixing cavity having side walls and a bottom surface; and
a plurality of red, green, and blue light emitting diodes (LEDs) arranged in the mixing cavity in an array;
the LEDs being arranged in clusters, the clusters comprising at least a first type and a second type, with the first type and second type having the same number of LEDs and the same ratio of red, green, and blue LEDs.

2. The device of claim 1 wherein there are only two types of clusters in the array.

3. The device of claim 1 wherein the clusters are arranged in rows and columns.

4. The device of claim 3 wherein only clusters of the first type form a first set of rows and only clusters of the second type form a second set of rows.

5. The device of claim 4 wherein a row in the second set of rows is interleaved between rows in the first set of rows.

6. The device of claim 5 wherein there is an odd number of rows so that only the first cluster is at each of the four corners of the array.

7. The device of claim 3 wherein clusters of the first type and clusters of the second type alternate in a single row.

8. The device of claim 7 wherein clusters of the first type and cluster of the second type alternate in a single column such that clusters of the same type are not adjacent one another in a single row or column in the array.

9. The device of claim 1 wherein the first type of cluster and the second type of cluster are selected from the group consisting of RGBBGR and BGRRGB.

10. The device of claim 1 wherein the first type of cluster and the second type of cluster are selected from the group consisting of RBGGBR and GBRRBG.

11. The device of claim 1 wherein the first type of cluster and the second type of cluster are selected from the group consisting of GRBBRG and BRGGRB.

12. The device of claim 1 wherein the first type of cluster and the second type of cluster are selected from the group consisting of GRBRG and RGBGR.

13. The device of claim 1 wherein the first type and second type of clusters comprise a sequence of LEDs having an even number of LEDs, where the sequence is symmetric about a center line of the cluster.

14. The device of claim 1 wherein the first type and second type of clusters comprise a sequence of LEDs having an odd number of LEDs, where the sequence is symmetric about a center line of the cluster.

15. The device of claim 1 wherein the first type and second type of clusters comprise a sequence of LEDs, where the sequence is asymmetric about a center line of the cluster.

16. The device of claim 1 further comprising a liquid crystal layer overlying the mixing cavity for selectively controlling red, green, and blue pixels in a display screen.

17. The device of claim 16 wherein the display screen is a television screen.

18. The device of claim 1 wherein the first type of cluster and the second type of cluster each have six LEDs consisting of two reds, two green, and two blues, wherein the first type has LEDs in positions 1, 2, 3, 4, 5, and 6 in the cluster, wherein the second cluster has positions 1, 2, 3, 4, 5, and 6, and wherein the LEDs in positions 1 and 3 in the first type are switched for the second type, and the LEDs in positions 4 and 6 in the first type are switched for the second type.

19. A method of backlighting a display comprising:
providing a plurality of red, green, and blue light emitting diodes (LEDs) arranged in an array in a light mixing cavity, the LEDs being arranged in clusters, the clusters comprising at least a first type and a second type, with the first type and second type having the same number of LEDs and the same ratio of red, green, and blue LEDs;
energizing the clusters of LEDs;
mixing the red, green, and blue light emitted from the clusters in the mixing cavity;
providing at least one liquid crystal layer over the mixing cavity; and
controlling the at least one liquid crystal layer to control the brightness of red, green, and blue display pixels.

20. The method of claim 19 wherein the clusters are arranged in rows and columns, wherein only clusters of the first type form a first set of rows and only clusters of the second type form a second set of rows, and wherein a row in the second set of rows is interleaved between rows in the first set of rows.

21. The method of claim 20 wherein there is an odd number of rows so that only the first cluster is at each of the four corners of the array.

22. The method of claim 19 wherein the clusters are arranged in rows and columns, wherein clusters of the first type and cluster of the second type alternate in a single row, and wherein clusters of the first type and cluster of the second type alternate in a single column such that clusters of the same type are not adjacent one another in a single row or column in the array.

23. The method of claim 19 wherein the first type of cluster and the second type of cluster are selected from the group consisting of RGBBGR with BGRRGB; RBGGBR with GBRRBG; GRBBRG with BRGGRB; and GRBRG with RGBGR.
